(19) United States
(12) Patent Application Publication
(10) Pub. No.: US 2019/0211452 A1
(43) Pub. Date: Jul. 11, 2019

(54) PLASMA ENHANCED CHEMICAL VAPOR DEPOSITION EQUIPMENT

(71) Applicants: BOE Technology Group Co., Ltd., Beijing (CN); Chongqing BOE Optoelectronics Technology Co., Ltd, Chongqing (CN)

(72) Inventors: Ji Hoon KIM, Beijing (CN); Qingyou WU, Beijing (CN)

(21) Appl. No.: 16/129,587

(22) Filed: Sep. 12, 2018

(30) Foreign Application Priority Data
Jan. 9, 2018 (CN) 201820036828.6

(51) Int. Cl. C23C 16/50; C23C 16/44; H01J 37/32

(52) U.S. Cl. CPC C23C 16/50; C23C 16/4409; H01J 2237/3321; H01J 37/32743; H01J 37/32788; H01J 37/32532

(57) ABSTRACT

A PECVD equipment includes: a process chamber, a sample transfer passage and a vacuum valve. The process chamber is formed, in a wall thereof, with a sample inlet communicated with the process chamber, and the process chamber is provided therein with a first plate electrode and a second plate electrode that are opposite to each other. The sample transfer passage is communicated with the sample inlet so that a sample is transferred from the sample transfer passage to the process chamber through the sample inlet. The vacuum valve is detachably provided at the sample transfer passage and includes a first flat valve gate. The vacuum valve is configured so that, when the PECVD equipment is in an operating state, the first flat valve gate is moved to a position, that is closer to the sample inlet, in the sample transfer passage to seal the sample inlet.

### CROSS-REFERENCE TO RELATED APPLICATION

This application claims priority to Chinese Patent Application No. 201820036828.6 filed on Jan. 9, 2018 in the Intellectual Property Office of China, the disclosure of which is hereby incorporated by reference in its entirety.

### TECHNICAL FIELD

The present disclosure relates to the field of thin film deposition technology in display fabrication, and particularly, to a plasma enhanced chemical vapor deposition (herein shorted as PECVD) equipment.

### BACKGROUND

In the field of flat panel display, TFT-LCD (Thin Film Transistor Liquid Crystal Display) has been widely used in real life due to its characteristics including low power consumption, high resolution, high color saturation and low cost. Generally, a liquid crystal display mainly includes a display screen, a driving circuit, and a backlight. The display screen mainly includes a color film, a liquid crystal, a thin film field effect transistor (TFT) substrate, and a polarizer. The TFT substrate is generally formed by exposing and etching metal films and non-metal films through a plurality of mask processes. A metal insulating layer, a semiconductor film layer, and a passivation protective layer in the TFT structure are all non-metal films, and the degree of uniformity of the non-metal films affects the life and quality of the TFT-LCD panel.

With the development of the TFT-LCD industry, the equipment is becoming larger and larger. In the structural design of conventional PECVD equipment, unique shape of a sample transfer passage that is between a process chamber and a vacuum valve (Slit Valve) causes uneven distribution of the plasma density, resulting in poor uniformity of film.

As such, the structural design of conventional PECVD equipment for preparation of non-metallic films should to be improved.

### SUMMARY

According to an aspect of the present disclosure, there is provided a PECVD equipment comprising: a process chamber formed, in a wall thereof, with a sample inlet communicated with the process chamber, the process chamber being provided therein with a first plate electrode and a second plate electrode that are opposite to each other; a sample transfer passage communicated with the sample inlet so that a sample is transferred from the sample transfer passage to the process chamber through the sample inlet; a vacuum valve detachably provided at the sample transfer passage and comprising a first flat valve gate; wherein, the vacuum valve is configured so that, when the PECVD equipment is in an operating state, the first flat valve gate is moved to a position, that is closer to the sample inlet, in the sample transfer passage to seal the sample inlet.

In some embodiments, a stop member is provided at a connection between the sample inlet and the sample transfer passage and is configured to match with the first flat valve gate so as to seal the sample inlet.

In some embodiments, the stop member is annular and is provided around the sample inlet.

In some embodiments, the stop member comprises a sealing ring.

In some embodiments, the PECVD equipment further comprises: a transfer chamber formed, in a wall thereof, with a sample outlet from which the sample is transferred to the process chamber via the sample transfer passage.

In some embodiments, the vacuum valve further comprises a second flat valve gate, and the vacuum valve is further configured so that, when the PECVD equipment is in an operating state, the second flat valve gate is moved to the sample outlet to seal the sample outlet.

In some embodiments, the vacuum valve further comprises a first retractable rod connected with the first flat valve gate and a second retractable rod connected with the second flat valve gate.

In some embodiments, the process chamber has a length of about 2 m to about 5 m.

In some embodiments, the sample transfer passage has a length of about 0.1 m to about 0.5 m.

In some embodiments, the first retractable rod has a retractable length of about 0.1 m to about 0.5 m.

In some embodiments, the retractable length of the first retractable rod is not less than a length of the sample transfer passage.

In some embodiments, the PECVD equipment further comprises a plurality of said process chambers.

In some embodiments, the vacuum valve is further configured so that, when the PECVD equipment is in a non-operating state, the vacuum valve is removed between the process chamber, the sample transfer passage and the transfer chamber, so as to communicate the sample inlet with the sample outlet.

### BRIEF DESCRIPTION OF THE DRAWINGS

The above and/or additional aspects and advantages of the present disclosure will become apparent and readily understood from the following description in conjunction with the attached drawings, in which:

FIG. 1 is a schematic view showing a structure of a PECVD equipment in related art;

FIG. 2 is a three-dimensional map of a thickness of a thin film fabricated by the PECVD equipment in related art;

FIG. 3 is a schematic view showing a structure of a PECVD equipment according to an embodiment of the present disclosure;

FIG. 4 is a schematic view showing a structure of a PECVD equipment according to another embodiment of the present disclosure;

FIG. 5 is a schematic view showing a structure of a PECVD equipment according to yet another embodiment of the present disclosure; and

FIG. 6 is a schematic view showing a structure of a PECVD equipment according to still another embodiment of the present disclosure.

### DETAILED DESCRIPTION OF THE EMBODIMENTS

The present disclosure is intended to solve or alleviate at least one of the technical problems in the related art to some extent.

The present disclosure is based on the following findings of the inventors.

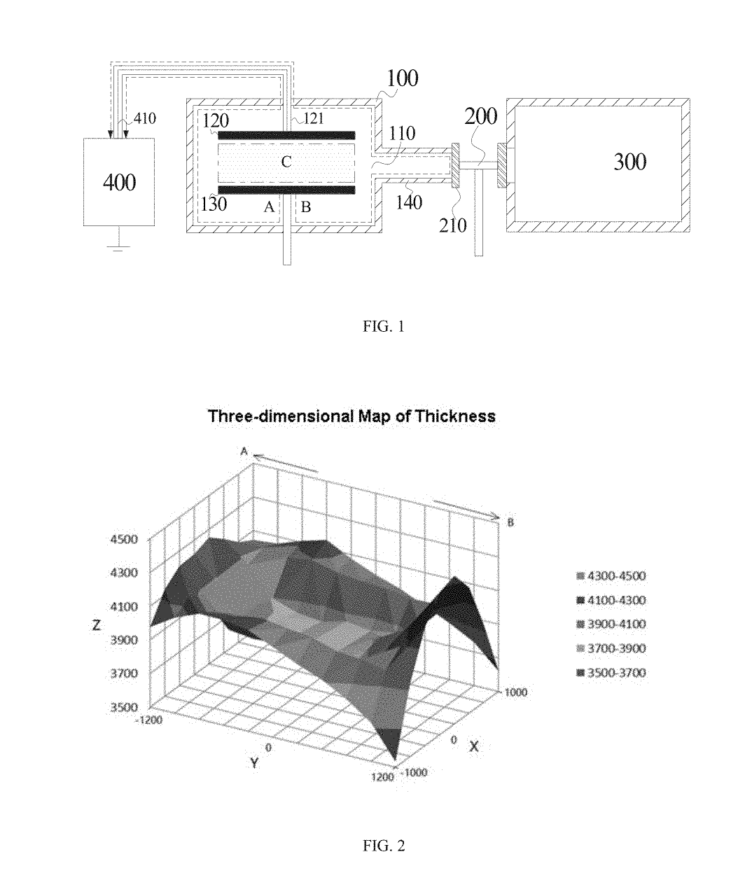

It is found by the inventors in research process that, referring to FIG. 1 which shows specific structure of conventional PECVD equipment, a vacuum valve (Slit Valve) 200 is generally used between a process chamber 100 and a transfer chamber 300 to ensure the sealing under operating states. A sample transfer passage 140 is provided at a sample inlet 110 formed at a side of the process chamber 100 closing to the transfer chamber 300. This left-right asymmetrical structure causes a difference in distance between loop currents A and B (in which loop current A is farther from the sample inlet 110 while loop current B is closer to the sample inlet 110) started from the second electrode plate 130 when a deposition occurs within the process chamber 100 in an operating state. With the increase of the generation line, an area of a thin film deposition substrate increases and a size of the PECVD equipment increases, which will increase the difference in distance between the loop currents A and B, thereby causing uneven distribution of the plasma in the deposition process. Thickness of a part of the deposited thin film increases (refer to FIG. 2), which in turn leads to poor film uniformity, called the vacuum valve (Slit Valve) effect, thereby ultimately leading to quality problems. In addition, from FIG. 2 which shows a three-dimensional map of a thickness of a thin film, it is learned that, for a deposited non-metallic film having a required thickness of 4000 Å (400 nm), an actual thickness measured is from about 3500 Å to about 4400 Å (see FIG. 2, an X-axis and an Y-axis indicate the non-metallic thin film at different positions, while an Z-axis indicates a thickness of the non-metallic thin film at different positions), and the film uniformity is poor. Obviously, a thickness difference in the direction of the loop current B (i.e., a different between a maximum thickness of about 4300 Å and a minimum thickness of about 3500 Å is about 800 Å) is significantly greater than a thickness difference in the direction of the loop current A (i.e., a different between a maximum thickness of about 4000 Å and a minimum thickness of about 4300 Å is about 300 Å).

It is found by the inventors in further study that, when the PECVD equipment is in an operating state, a first flat valve gate of the vacuum valve can be extended into the sample transfer passage to seal the sample inlet of the process chamber. Thus, for a PECVD equipment including a process chamber having a sample transfer passage of specific shape, the difference in distance between left and right loop currents A and B when the PECVD equipment is in an operating state is effectively reduced, which avoids the vacuum valve (Slit Valve) effect, and achieves an even distribution of plasma density between the first plate electrode and the second plate electrode in the process chamber, thereby effectively improving the uniformity of thickness of the non-metal thin film deposited and thus improving the life and quality of the display device.

In view of the above, at least one object of the present disclosure is to provide a PECVD equipment which effectively improves the uniformity of a non-metal thin film.

The embodiments of the present disclosure are described in detail below, and those skilled in the art will understand that the following embodiments are intended to explain the present disclosure, and should not be constructed to limiting the present disclosure. Unless specifically stated otherwise, if specific techniques or conditions are not explicitly described in the following embodiments, those skilled in the art can carry out according to commonly used techniques or conditions in the art or according to the product specifications.

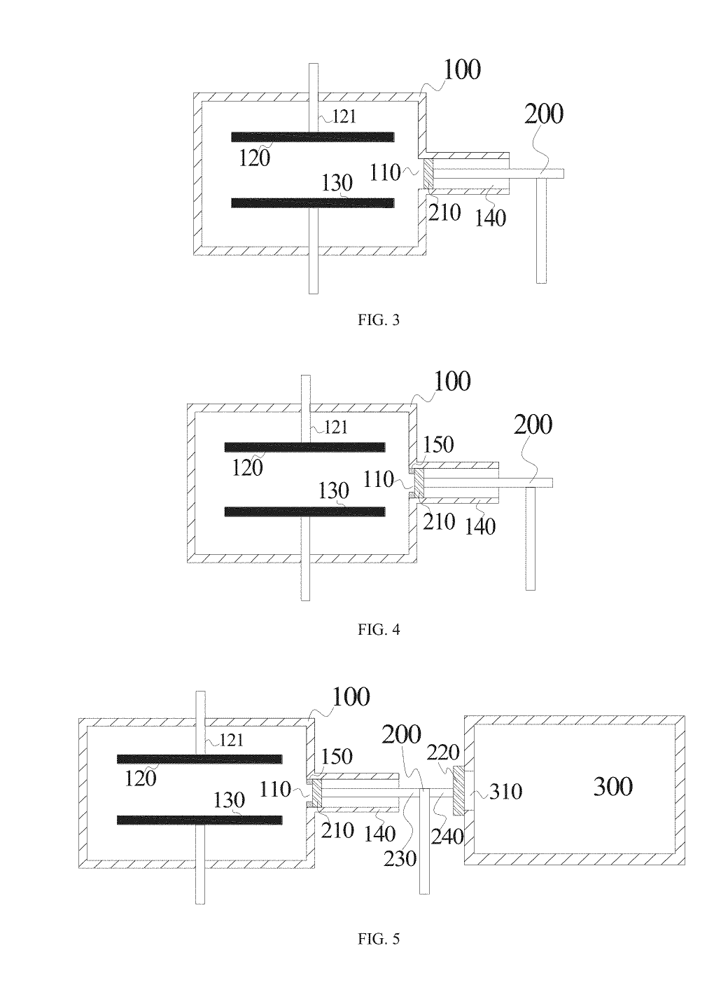

In accordance with an aspect of the present disclosure, there is provided a PECVD equipment. Referring to FIG. 3 to FIG. 6, the PECVD equipment according to an embodiment of the present disclosure will be described in detail.

According to an embodiment of the present disclosure, referring to FIG. 3, a PECVD equipment comprises: a process chamber 100, a sample transfer passage 140 and a vacuum valve 200. A sample inlet 110 communicated with the process chamber 100 is formed in a wall of the process chamber 100, and the process chamber 100 is provided therein with a first plate electrode 120 and a second plate electrode 130 that are opposite to each other. The sample transfer passage 140 is communicated with the sample inlet 110 so that a sample can be transferred from the sample transfer passage 140 to the process chamber 100 through the sample inlet 110. The vacuum valve 200 is detachably provided at the sample transfer passage 140 to seal the sample inlet 110 and comprises a first flat valve gate 210. The vacuum valve is configured so that, when the PECVD equipment is in an operating state, the first flat valve gate 210 is moved to a position, that is closer to the sample inlet 110, in the sample transfer passage 140 to seal the sample inlet 110. It should be noted that, “in an operating state” described herein may indicate that the PECVD equipment implements a PECVD thin film deposition process on a sample, while “sample” described herein may indicate a substrate to be implemented with a PECVD thin film deposition process, for example, a glass substrate.

It is found by the inventors in long-term research that, provision of the sample transfer passage 140 in a design of the process chamber 100 causes uneven distribution of the plasma density. By changing a location of the first flat valve gate 210 in the vacuum valve 200, the first flat valve gate 210 can be used to seal the sample inlet 110 when the PECVD equipment is in an operating state, so that the difference in distance between left and right loop currents A and B in the process chamber 100 is significantly reduced, thereby improving the uniformity of thickness of the non-metal thin film deposited between the first plate electrode 120 and the second plate electrode 130.

According to an embodiment of the present disclosure, referring to FIG. 4, a stop member 150 is provided at a connection between the sample inlet 110 and the sample transfer passage 140, and the stop member 150 is configured to match with the first flat valve gate 210 so as to seal the sample inlet 110. In this way, when the first flat valve gate 210 in the sample transfer passage 140 moves to the sample inlet 110, the first flat valve gate 210 is stopped by the stop member 150 and matches with the stop member 150 to seal the sample inlet 110.

According to the embodiment of the present disclosure, the stop member 150 is annular and is provided around the sample inlet 110. Dimension and shape of the stop member 150 are the same as inner diameter and shape of the sample transfer passage 140 at the sample inlet 110. In this way, a seal is achieved between the first flat valve gate 210 and the sample transfer passage 140, thereby ensuring the sealing at the sample inlet 110.

According to embodiments of the present disclosure, material of the stop member 150 is not particularly limited as long as the performance of the stop member 150 made of the material can ensure the sealing of the process chamber 100, and those skilled in the art can select a material according to the pressure requirements of the process chamber under operating states. In some embodiments of the present disclosure, the stop member 150 may include a sealing ring, and thus, using the sealing ring as a part of the stop member 150 may further ensure the sealing at the sample inlet 110, thereby ensuring the vacuum requirement of the process chamber 100 under operating states. As a result, the thickness uniformity of the formed non-metal film is further improved.

According to an embodiment of the present disclosure, referring to FIG. 5, the PECVD equipment may further comprise a transfer chamber 300 formed, in a wall thereof, with a sample outlet 310 from which the sample is transferred to the process chamber 100 via the sample transfer passage 140.

According to embodiments of the present disclosure, the number of process chambers 100 can be multiple, and a corresponding number of sample outlets can be formed on the transfer chamber 300. In this way, in the non-operating state of the PECVD equipment, the sample (substrate) to be deposited can be transferred between a plurality of process chambers through the transfer chamber, thereby enabling continuous deposition of a plurality of different non-metal thin films. It would be noted that the number of the process chamber 100 and the number of the corresponding sample outlets on the transfer chamber 300 are not particularly limited, and those skilled in the art can determine and adjust them according to the specific layer structure in the array substrate to be formed.

According to an embodiment of the present disclosure, referring to FIG. 5, the vacuum valve 200 may further comprise a second flat valve gate 220. When the PECVD equipment is in an operating state, the second flat valve gate 220 seals the sample outlet 310. In this way, When in an operating state, the vacuum valve 200 not only seals the sample inlet 110 of the process chamber 100 through the first flat valve gate 210, but also seals the sample outlet 310 of the transfer chamber 300 through the second flat valve gate 220.

According to an embodiment of the present disclosure, referring to FIG. 5, the vacuum valve 200 may further comprise a first retractable rod 230 connected with the first flat valve gate 210 and a second retractable rod 240 connected with the second flat valve gate 220. In this way, when the process chamber 100 does not need a high vacuum condition after the operating states is over, the first flat valve gate 210 can be separated from the sample inlet 110 and exited from the sample transfer passage 140 by the retraction of the first retractable rod 230, and the second flat valve gate 220 can be exited from the sample outlet 310 by the retraction of the second retractable rod 240. Then, the vacuum valve 200 can be withdrawn from between the process chamber 100 and the transfer chamber 300 to allow the sample inlet 110 to communicate with the sample outlet 310, so that the sample (substrate) can be transferred between the transfer chamber 300 and the process chamber 100 by means of transfer arm.

According to an embodiment of the present disclosure, the process chamber 100 may have a length of about 2 m to about 5 m. In this way, the process chamber 100 of the abovementioned size can meet the increased development requirements of existing thin film deposition substrates. It should be noted that the length of the process chamber indicates specifically a maximum distance of the process chamber, excepting the sample transfer passage, in the horizontal direction as shown. In some embodiments of the present disclosure, the length of the process chamber 100 may be about 2.5 m, thereby meeting the production size requirements of the existing thin film deposition substrate.

According to an embodiment of the present disclosure, the sample transfer passage 100 may have a length of about 0.1 m to about 0.5 m. In this way, with the sample transfer passage 140 of the abovementioned size, even if the area of the conventional thin film deposition substrate is increased and the PECVD equipment is enlarged, no plasma distribution unevenness is caused during the deposition process, so that the life of the enlarged substrate sample is increased and the quality is improved. It should be noted that the length of the sample transfer passage 140 specifically indicates a maximum distance between the sample inlet and the other opening of the process chamber in the horizontal direction as shown.

According to an embodiment of the present disclosure, the first retractable rod 230 may have a retractable length of about 0.1 m to about 0.5 m. In this way, as long as the retractable length of the first retractable rod 230 is not less than the length of the sample transfer passage 140, the sealing of the sample inlet 110 by the first flat valve gate 210 can be achieved.

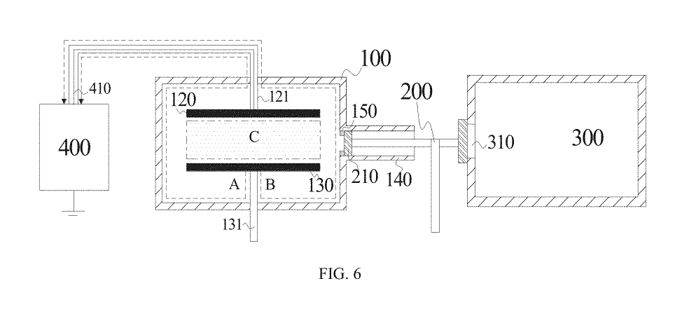

According to some embodiments of the present disclosure, referring to FIG. 6, the PECVD equipment may further comprise a radio frequency power source 400 having a wire 410 electrically coupled from the interior of a hollow first copper tube 121 to the first plate electrode 120. It should be noted that, in FIG. 6, the first copper tube 121 and the first plate electrode 120 are connected to each other, but are physically insulated from each other. As such, the radio frequency power source 400 can provide radio frequency current to the first plate electrode 120 through the wire 410 during operating state, thereby generating a glow region C between the first plate electrode 120 and the second plate electrode 130, and plasma in the glow region C is deposited onto the sample (substrate) on the second plate electrode 130. Simultaneously, the formed loop currents A, B are transmitted from the second plate electrode 130 downwards to the second copper tube 131, then to bottom wall, side wall and top wall of the process chamber 100, and finally return to the radio frequency power source 400 along outer wall of the first copper tube 121, thereby to form an electrical circuit loop with the radio frequency current in the copper tube 121. In addition, since the first flat valve gate 210 seals the sample inlet 110 when in the operating state, the loop current B that is closer to the sample inlet 110 is not additionally bypassed in the sample transfer passage 140, so that the difference in distance between the loop currents A and B in the process chamber 100 is significantly reduced, the plasma density on the sample (substrate) is more uniform, and the film formed after deposition is more uniform. For example, when a non-metallic film of 4000 Å is deposited, the actual thickness measured is about 4000 Å˜4400 Å, that is, the thickness uniformity is better, which can improve the life and quality of the display panel.

According to embodiments of the present disclosure, cross-sectional shape and height of the process chamber 100 are not particularly limited, and those skilled in the art can determine them according to specific shape of the sample (substrate) and specific height of the glow region C, and details are not described herein again.

According to embodiments of the present disclosure, cross-sectional shape and size of the transfer chamber 300 are not particularly limited, and those skilled in the art can determine them according to specific shape of the sample (substrate) and actual needs of the production line, and details are not described herein again.

According to embodiments of the present disclosure, diameters of the first plate electrode 120 and the second plate electrode 130 and specific distance between the two are not particularly limited, and those skilled in the art can determine them according to specific size of the sample (substrate) and specific material of the non-metal film to be formed, and details are not described herein again.

According to embodiments of the present disclosure, size of the first flat valve gate 210 is not particularly limited as long as the first flat valve gate 210 can reach into the sample transfer passage 140, those skilled in the art can adjust it according to specific shape of the sample transfer passage 140, and details are not described herein again. According to embodiments of the present disclosure, shape and size of the second flat valve gate 220 are also not particularly limited as long as the second flat valve gate 220 can seal the sample outlet 310, and those skilled in the art can determine them according to specific shape and size of the sample outlet 310.

From the foregoing, according to embodiments of the present disclosure, the present disclosure proposes a PECVD equipment. When in the operating state of the PECVD equipment, the first flat valve gate of the vacuum valve reaches into the sample transfer passage and seals the sample inlet of the process chamber. In this way, even if the process chamber of the PECVD equipment has a sample transfer passage of specific shape, the difference in distance between left and right loop currents is effectively reduced in the operating state, thereby uniformizing the plasma distribution between the first plate electrode and the second plate electrode, thereby further effectively improving the uniformity of the non-metallic film deposited and improving the life and quality of the display device.

In the present description, it should be understood that orientation or positional relationship indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like is based on the orientation or positional relationship shown in the attached drawings, and is merely for the convenience of describing the present disclosure and simplifying the description, and does not indicate or imply the indicated device or element must have a particular orientation, is constructed and operated in particular orientation, and thus are not to be construed as limiting the present disclosure.

In the present description, unless specifically defined otherwise, the terms “mount”, “connect to”, “connect with”, “fix”, and the like, are to be understood broadly. For example, it may be a fixed connection or a detachable connection or to be integrated; it may be a mechanical connection or an electrical connection; it may be a direct connection or an indirect connection through an intermediate medium; and it may be an internal connection of two elements or an interaction relationship of two elements. For those skilled in the art, the specific meanings of the above terms in the present description can be understood on a case-by-case basis.

In addition, the terms “first” and “second” are used for descriptive purposes only and are not to be construed as indicating or implying a relative importance or implicitly indicating the number of technical features indicated. Thus, features with “first” or “second” may include at least one of the features, either explicitly or implicitly. In the present description, the term “a plurality of” means at least two, such as two, three, etc., unless specifically defined otherwise.

In the present description, expressions with the terms “one embodiment”, “some embodiments”, “example”, “specific example”, or “some examples” and the like mean that specific feature, structure, material, or characteristic described in the embodiment or example is included in at least one embodiment or example of the present disclosure. In the present description, schematic expression of the above terms is not necessarily directed to the same embodiment or example. Furthermore, specific features, structures, materials, or characteristics described may be combined in a suitable manner in any one or more embodiments or examples. In addition, in the absence of contradiction, various embodiments or examples described in the description, as well as features of various embodiments or examples, may be combined, for those skilled in the art.

Although some embodiments of the present disclosure have been shown and described as above, the embodiments described are merely exemplary and are not intended to limit the present disclosure. Variations, modifications, alterations and variations of the above-described embodiments may be made by those skilled in the art within the scope of the present disclosure, the scope of which is defined in the attached claims.

What is claimed is:

1. A plasma enhanced chemical vapor deposition (PECVD) equipment comprising:
a process chamber formed, in a wall thereof, with a sample inlet communicating with the process chamber, the process chamber being provided therein with a first plate electrode and a second plate electrode that are opposite to each other;
a sample transfer passage communicating with the sample inlet so that a sample is transferred from the sample transfer passage to the process chamber through the sample inlet; and
a vacuum valve detachably provided at the sample transfer passage and comprising a first flat valve gate;
wherein, the vacuum valve is configured so that, when the PECVD equipment is in an operating state, the first flat valve gate is moved to a position, that is closer to the sample inlet, in the sample transfer passage to seal the sample inlet.

2. The PECVD equipment of claim 1, wherein a stop member is provided at a connection between the sample inlet and the sample transfer passage and is configured to match with the first flat valve gate so as to seal the sample inlet.

3. The PECVD equipment of claim 2, wherein the stop member is annular and is provided around the sample inlet.

4. The PECVD equipment of claim 3, wherein the stop member comprises a sealing ring.

5. The PECVD equipment of claim 1, further comprising:
a transfer chamber formed, in a wall thereof, with a sample outlet from which the sample is transferred to the process chamber via the sample transfer passage.

6. The PECVD equipment of claim 5, wherein the vacuum valve further comprises a second flat valve gate, and the vacuum valve is further configured so that, when the PECVD equipment is in an operating state, the second flat valve gate is moved to the sample outlet to seal the sample outlet.

7. The PECVD equipment of claim 6, wherein the vacuum valve further comprises a first retractable rod connected with the first flat valve gate and a second retractable rod connected with the second flat valve gate.

8. The PECVD equipment of claim 1, wherein the process chamber has a length of about 2 m to about 5 m.

9. The PECVD equipment of claim 1, wherein the sample transfer passage has a length of about 0.1 m to about 0.5 m.

10. The PECVD equipment of claim 7, wherein the first retractable rod has a retractable length of about 0.1 m to about 0.5 m.

11. The PECVD equipment of claim 10, wherein the retractable length of the first retractable rod is not less than a length of the sample transfer passage.

12. The PECVD equipment of claim 1, further comprising a plurality of said process chambers.

13. The PECVD equipment of claim 6, wherein the vacuum valve is further configured so that, when the PECVD equipment is in a non-operating state, the vacuum valve is removed between the process chamber, the sample transfer passage and the transfer chamber, so as to communicate with the sample inlet with the sample outlet.
